(19) United States
(12) Patent Application Publication
(10) Pub. No.: US 2006/0048698 A1
(43) Pub. Date: Mar. 9, 2006

(54) Methods and systems for purifying elements

(75) Inventors: Robert B. Hall, Marana, AZ (US); Scott L. Kendall, Berlin, MD (US); James A. Rand, Landenberg, PA (US); Paul E. Sims, Pittsboro, NC (US)

Correspondence Address: BURR & BROWN, PO BOX 7068, SYRACUSE, NY, 13261-7068, US

(73) Assignee: GE ENERGY (USA) LLC, Atlanta, GA (US)

(21) Appl. No.: 10/529,350

(22) PCT Filed: Sep. 26, 2003
(86) PCT No.: PCT/US03/30659

§ 371 Date: Mar. 25, 2005

Related U.S. Application Data
(60) Provisional application No. 60/414,052, filed on Sep. 27, 2002.

(51) Int. Cl. C30B 13/00; C30B 19/00

(52) U.S. Cl. 117/54

(57) ABSTRACT

There are provided methods of purifying a material, comprising melting solid material to form liquefied material, directionally solidifying a portion of the liquefied material; and removing a liquid remainder from the purified solidified material. Preferably, the purified solidified material is melted to form re-liquefied purified material, and re-liquefied purified material is removed. Preferably, the material is positioned in a container as it is being purified. The method is particularly useful for purifying elemental material, e.g., semiconductor material such as silicon and/or germanium, such as recycle scrap silicon and/or metallurgical grade silicon. There are also provided systems for carrying out such methods.

### CROSS REFERENCE TO RELATED APPLICATION

This application claims the benefit of U.S. Provisional Application Ser. No. 60/414,052 filed Sep. 27, 2002, the entirety of which is incorporated herein by reference.

### FIELD OF THE INVENTION

The present invention relates to methods and systems for purifying elements. In one aspect, the present invention is directed to methods and systems for purifying semiconductor elements, e.g., silicon and germanium. In a specific aspect, the present invention relates to purification of metallurgical-grade silicon and/or scrap silicon into solar-grade silicon.

### BACKGROUND OF THE INVENTION

Purified elemental material is used for a variety of purposes. For instance, purified semiconductor elemental material is needed for a variety of applications, and there is an ever-increasing demand for such material in most, if not all, of such applications.

Currently, silicon is the most commonly used semiconductor material, e.g., for making semiconductor wafers. Where the expression “semiconductor” or the expression “semiconductor material” is used herein, the discussion in particular relates to silicon. However, those of skill in the art will readily appreciate that in many instances, other semiconductor materials could be substituted for silicon with analogous results.

For example, solar-electric systems typically employ a semiconductor substrate, typically made of silicon (single crystal or polycrystalline), especially for deployment at or near the surface of the earth. Solar-electric systems have become more and more common, and of greater and greater importance. The use of solar-electric systems is expected to increase, potentially dramatically. As such, improvements in solar-electric technology, even incremental improvements, are of great importance.

A significant portion of the cost of such semiconductor material is the semiconductor material itself. For example, in the case of solar-electric systems, a primary factor which has limited the use of such systems is the cost of the semiconductor material in the semiconductor wafers (in particular, silicon) needed for such systems.

It has been repeatedly stated that in order for the immense potential benefits of solar-electric power to be fully realized, it will be necessary to provide solar-grade semiconductor material at costs by which the solar-electric industry can remain competitive with other forms of energy. Indeed, many feel that the driving force which will allow solar-electric power to become a dominant source of energy will be reductions in the cost of solar-grade semiconductor material.

The crystalline silicon solar cell industry is quickly running out of cost-effective feedstock. The prevailing approach for manufacturing silicon feedstock has been well developed for the semiconductor industry (i.e., production of semiconductor-grade silicon), but does not meet the requirements for the production of large amounts of cheap, moderate purity, solar-grade solid-silicon feedstock. The current cost for solar-grade silicon and semiconductor-grade silicon using chemical processes is essentially the same (currently about $50/kg). Silicon solar feedstock technology has been piggybacking on the semiconductor industry for the past thirty-five years. A mandatory requirement for the development of a thriving solar power industry is the development of a cheaper silicon feedstock that does not have the high purity requirements of the semiconductor wafer industry—the solar-grade silicon feedstock supply must be decoupled from the semiconductor silicon feedstock industry in order to be able to provide the benefits it offers to mankind. For even a moderate growth of the solar industry (10% per year), the future supply of silicon feedstock is in question.

Accordingly, there is an ongoing need for a more cost effective supply of silicon feedstock for solar-electric applications.

### BRIEF SUMMARY OF THE INVENTION

According to the present invention, there are provided methods and systems by which elemental materials can be purified in a cost-effective manner. In addition, according to the present invention, semiconductor material, e.g., elemental silicon and/or elemental germanium, can be purified in a cost-effective manner, which does not rely on methods for producing semiconductor-grade material. In a preferred aspect, the present invention provides for purification of metallurgical-grade silicon and/or scrap silicon into solar-grade silicon.

According to the present invention, there are provided methods of purifying a material, each such method comprising:

melting solid material to form liquefied material;

at least one treatment cycle, each such treatment cycle comprising directionally solidifying a portion of the liquefied material to convert the liquefied material to a combination of purified solidified material and liquid remainder; and then removing the liquid remainder from the purified solidified material.

The at least one treatment cycle according to the present invention preferably further comprises melting the purified solidified material to form re-liquefied purified material.

Preferably, according to the above methods, a batch of solid material is deposited in a container prior to being melted, and the batch is then subjected to one or more treatment cycle while positioned in the container. Preferably, each such container is recycled, i.e., is used to sequentially process each of a plurality of batches according to such a process.

Preferably, after completion of the at least one treatment cycle, the batch of purified material is removed from the container (as a liquid, as a solid, or as a combination of liquid and solid).

Preferably, each such batch is moved sequentially through the process elements described above.

In a preferred aspect of the present invention, the solid material comprises at least 95% silicon or at least 95% germanium. Preferably, the solid material comprises recycle scrap silicon and/or metallurgical grade silicon.

The present invention further provides systems for purifying a material, each such system comprising:

at least one container;

a first melter which can create conditions under which a material being treated will melt to form a liquefied material;

a solidifier which can create conditions under which a part of said liquefied material will directionally solidify to convert the liquefied material to a combination of purified solidified material and liquid remainder;

a liquid remover which can remove the liquid remainder from the container; and

a second melter which can create conditions under which the purified solidified material melts to form a re-liquefied purified material.

Such system preferably further comprises a material supplier which can supply material to the container; and a second liquid remover which can remove the re-liquefied purified material from the container. Preferably, at least one radiation plate is positioned such that during at least part of the time when the container is in the solidifier, the radiation plate will be between the solidifier and the container.

The present invention thus provides methods and systems for providing silicon feedstock for solar-electric applications more cost effectively than existing methods and systems. The methods and systems of the present invention provide a manufacturing-compatible-processing method to effect purification, including means for continuously removing impurity-laden material.

The invention may be more fully understood with reference to the accompanying drawings and the following detailed description of the invention.

### BRIEF DESCRIPTION OF THE DRAWINGS FIGURES

FIG. 1 is a schematic representation of an embodiment of a continuous uni-directional solidification furnace suitable for use in accordance with the present invention.

FIG. 2 is a cross-sectional view along line II-II in FIG. 1.

### DETAILED DESCRIPTION OF THE INVENTION

The raw material treated by the methods according to the present invention and/or supplied to systems according to the present invention is generally any material containing the element or elements being purified, preferably any material which readily exists in a liquid state (e.g., silicon, germanium, aluminum, iron, etc.). For example, in cases where solar-grade silicon is sought, the input can be any silicon-containing material, e.g., metallurgical silicon, recycle scrap silicon, etc. Where solar-grade silicon is sought, one example of a suitable raw material is metallurgical silicon having a purity level of 98 to 99% (major impurities being Al, Fe, Ca, and/or Ti), selected or processed to have concentrations of B and P less than 10 ppmw.

The raw material is deposited into a container, e.g., a crucible. The raw material may be liquid or solid (or a mixture of liquid and solid) when it is deposited into a container.

Where the raw material is solid, it is preferably in the form of particles. If the raw material is provided in the form of chunks, it is preferably crushed, using any suitable technique (e.g., any conventional technique), prior to being deposited into a container.

Small amounts of pure silicon oxide (0.1 to 1.0% by mass) maybe added to the raw material before it is melted. The addition of silicon oxide enhances the formation of a slag on the surface of the fully melted raw material, e.g., silicon, and assists in the removal of impurities such as SiC and, for example, B, Fe, Al, Ca, Ti and P. Combinations of this additive and the use of reactive gases (discussed below) is particularly preferred for the removal of impurities. Preferably, the size of the silicon oxide-bearing particles, if employed, is in the range of from about 0.1 to about 1.0 micrometers. The utilization of particles in this size range allows for an effective distribution in the liquid raw material, e.g., silicon, of the silicon oxide, thereby making the silicon oxide readily available for reduction to more stable oxides (e.g. of Ca, Al, Ti), which can subsequently be captured in the slag that forms on the free surface of the liquid raw material.

In a further preferred embodiment, a small amount of pure silicon nitride (0.1 to 3.0% by mass) can be added to the solid raw material, e.g., silicon feedstock. This addition enhances the formation of a slag on the surface of the fully melted raw material. The size of the silicon nitride-bearing particles is preferably in the range of from about 0.1 to 1.0 about micrometers. The utilization of particles in this size range allows for an effective distribution in the liquid raw material, e.g., silicon, of the silicon nitride, making it readily available for reduction to more stable nitrides (e.g. B) which can subsequently be captured in the slag that forms on the free surface of the liquid raw material.

The utilization of pure silicon oxide and silicon nitride as additives may be executed independently in separate treatment cycles, or in combination in a single treatment cycle. Other oxide or nitride additives can also be employed, the criteria for selection being that the additive(s) need to not add impurities to the melt, and need to be less stable than the elements that are being targeted for removal (e.g. Ca, Al, Ti, B). In a preferred embodiment, an oxide additive is employed during a first directional solidification purification pass (treatment cycle), and a nitride is employed during a second directional solidification purification pass.

Each container is made of any material which can withstand the temperatures necessary to melt the raw material being purified, and which does not contaminate the purified material. For example, suitable materials out of which containers can be made include graphite, SiO₂ and quartz. The thicknesses of the walls of the container are preferably minimized, without compromising their structural integrity in the conditions to which the containers are exposed. In addition, the container preferably is made of a material (i.e., a non-stick material) which does not adhere strongly to the purified material, and/or the inside of the container preferably has a coating of a release agent in order to facilitate separation of the purified material from the walls of the container. For example, a release agent coating can be applied (e.g., by any suitable spraying method, e.g., a conventional spraying method) to the inside walls of the container before depositing raw material in the container. Preferred non-stick materials and release agents include silicon nitride, silicon oxynitride, silica, powdered silicon, alumina, silicon carbide, carbon and combinations thereof. Use of such a non-stick container or release agent is especially preferred in instances where the purified material is not re-liquefied after directional solidification. In addition, the non-stick container or release agent can be important in avoiding the liquefied raw material or the re-liquefied purified material wetting the walls of the container when at elevated temperatures.

Where the raw material is a solid, e.g., a particulate, due to the difference between packing density of the solid feedstock and the density of the liquefied raw material, the capacity of the inside of the container needs to be larger than the volume of liquefied raw material.

As discussed below, the depth of the material being purified is preferably selected with consideration of the desired speed of the advancing planar/solid liquid interface (solidification front). The width and length dimensions of the container can generally be any suitable values. Accordingly, the desired capacity per container can preferably be provided by appropriate selection of width and length, with depth being selected in view of solidification front speed considerations.

Raw material is deposited in the container using any suitable apparatus, including any conventional raw material feeder. The raw material is preferably solid when it is deposited in the container.

As mentioned above, in cases where the raw material is solid as it is deposited into the containers, after placing the solid raw material into the container, the container and the raw material positioned in the container are subjected to conditions under which the raw material melts to form a liquid raw material. In general, any suitable device, e.g., heaters can be employed to provide such conditions. In a preferred embodiment, the raw material melting apparatus includes heaters positioned above and below the container, and insulation positioned along the inside of the walls of the furnace to minimize loss of heat through the walls of the furnace. Preferably, primarily the top heaters are used to melt the raw material so that melting occurs from the top down.

In a preferred aspect, the temperature of the container or the raw material is monitored in order to determine when the raw material has been completely or substantially completely melted (during melting, the temperature will remain substantially constant, and when melting is completed, the temperature will begin to increase). For example, where the material being purified is silicon, which has a relatively large heat of fusion, the temperature will increase until the melting point of silicon is reached, then the temperature will remain substantially constant for a time until all of the raw material (predominantly silicon) is melted, and then the temperature will begin to increase again, signaling that the raw material has been completely or substantially completely melted. In addition, if temperatures become higher than needed for the process of the invention (e.g., when purifying silicon, if the temperature of the container exceeds 1,500° C. or 1,600° C.), a determination can be made that less energy is required, leading to potential energy savings. Particularly useful for monitoring the temperature are infrared temperature detectors.

As described above, after the batch of raw material is melted, the batch is subjected to a thermal profile that effects directional solidification. Preferably, the solidification is a uni-directional solidification, i.e., a substantially planar solidification front travels in generally a single direction, preferably upward through the contents of the container. During the directional solidification, impurities having small segregation coefficients tend to remain in the liquid, and selectively move to the last surface to solidify.

The segregation coefficient is the equilibrium ratio of the solubility of an impurity element in the solid, e.g., solid silicon and the solubility of that impurity element in the liquid, e.g., liquid silicon. Small values of this coefficient (e.g., <10⁻³) imply high degrees of purification; lower values (e.g., >0.1) indicate very little purification attending solidification. By creating the thermal environment to have a planar solidification front occur uni-directionally, many impurities (e.g. Al, Ca, Fe, Ti, Ni, Cr, Cu) are collected at the last region to solidify.

There are several process considerations in effecting purification by uni-directional solidification. The degree of purification that can be realized in the purified solidified material is dependent on the velocity of the advancing planar liquid/solid solidification front. Preferably, the velocity of the advancing planar solidification front is not greater than about 0.2 cm/min in order to ensure adequate purification, but is preferably as large as possible (though preferably not greater than 0.2 cm/min) in order to maximize productivity (as well as to minimize overall system size). A major factor in this dependence is the impurity concentration in the fully melted raw material. To avoid constitutional supercooling (i.e. the breakdown of the planar solid/liquid solidification growth front) and achieve effective purification, it is preferred that the planar solid/liquid growth front advance at less than 0.15 cm/min if the impurity concentrations are on the order of 300 ppmw (parts per million, by weight), and less than 0.2 cm /min if the impurity concentrations are on the order of 100 ppmw.

As the solid/liquid interface advances, the amount of the purified solidified material increases and the remaining volume of liquefied raw material decreases, leading to higher impurity concentration in the melt. This can result in the breakdown of the planar solidification front at the latter stages of the solidification process (e.g., approximately the last 5% of the thickness).

The rate at which the planar solid/liquid solidification front advances is determined by the rate at which the energy of solidification is removed. The removal of that energy normal to the plane of the solidification is given by: Q′=69*V_{g}, where Q′ is the power density (in watts/cm²) that must be removed to allow for the planar solid/liquid solidification front to advance at a velocity of V_{g} (in cm/min).

In general, it is preferred to have the manufacturing process proceed as fast as possible, and so the optimal rate for the advancement of the planar solid/liquid solidification front can be determined by the maximum velocity that will provide for purification, while avoiding constitutional supercooling. Using the growth rate criteria established above, it is desirable to limit the rate of energy density removal to between 7 and 14 watts/cm².

The management of energy in the uni-directional solidification apparatus is preferably accomplished by employing top heaters and a means for controlling the rate of heat removal from the bottom. The top heaters can be used to control the amount of heat energy provided to the top surface of the liquid silicon, and top thermal insulation can be used to enhance the efficiency of the top heaters.

The removal of the energy of solidification from the bottom surface of the container containing the batch is primarily accomplished by controlling the rate of heat removal. When heat is initially removed preferentially from the liquefied raw material through the bottom surface of the container, purified solidified material is formed leading to a planar liquid/solid interface. Control of the top heaters in conjunction with controlling heat removal allows for the continuous control of the rate at which the planar solid/liquid solidification front advances.

The rate of heat removal can be controlled by moderating radiation transfer from the bottom surface of the container. One suitable way to moderate radiation transfer is by using one or more radiation plates. Such radiation plates are preferably formed of any suitable non-contaminating material, e.g., graphite.

For example, in a preferred embodiment a low (nominally room) temperature radiation surface is provided by water-cooling a section of an outer metallic surface of a furnace. In such a configuration, the high temperature bottom surface of the container is, in the case of a process for purifying silicon, at temperature of, e.g., approximately 1700° K., and this radiates to the water-cooled section of the outer metallic surface of the furnace at a temperature of, e.g., approximately 300° K. In the simple case of two such parallel plates exchanging energy radiatively between surfaces having emissivities of, e.g., 0.5, the areal density of the energy transfer rate from the higher temperature body to the body at lower temperature is approximately 24 watts/cm². Since this areal density rate is greater than the targeted range of 7 to 14 watts/cm², radiation plates are preferably deployed between the bottom surface of the container and the water-cooled section of the outer metallic surface of the furnace to moderate the rate into the desired range. In a preferred embodiment, these radiation plates are fabricated from graphite.

In practice, during execution of the purification process, the temperature of the bottom surface of the container will decrease to lower temperatures. This decrease is necessary to maintain the temperature gradient necessary between the bottom surface of the container through the growing thickness of the purified solidified material. This temperature gradient is necessary to enable the removal of heat of solidification generated by the advancing solidification front, e.g., at a desired rate of 7 to 14 watt/cm².

The magnitude of the decreasing temperature of the bottom surface of the container affects the thickness of the purified solidified material which can be effectively formed. As temperatures get below 1400° K., the rate at which the bottom surface of the container can radiate heat away begins to fall significantly below the value for watts/cm which would maintain a growth rate of about 0.12 cm/min.

In a preferred aspect of the present invention, the depth of the purified solidified material is in the range of from about 4 cm to about 8 cm in order to assure that the speed of the advancing planar/solid liquid interface (solidification front) can be maintained at greater than about 0.12 cm/min. For growth rates less than this, the processing time becomes longer, leading to higher costs for a continuous manufacturing process. The width and length dimensions of the container can be any suitable values.

In a further preferred aspect of the present invention, the purified solidified material comprises from about 85% to 95%, by weight, of the melted raw material.

As mentioned above, after part of the liquefied raw material has been solidified to form a purified solidified material, leaving a liquid remainder, the (impurity-laden) liquid remainder is removed from the container. Any suitable apparatus for removing the liquid remainder can be employed. For example, one example of a preferred apparatus for removing the liquid remainder is a device which tips the container so as to pour the impurity-laden liquid remainder from the purified solidified material and into a receptacle for capturing and cooling the impurity-laden liquid remainder.

In some cases, the purified solidified material can be removed from the container without re-liquefying the purified solidified material. Such removal can, in such cases, be accomplished by simply removing the purified solidified material from the container or, if necessary, by first breaking the container and then removing the purified solidified material from the pieces of the container.

Preferably, however, after the liquid remainder is removed from the container, the purified solidified material is subjected to conditions under which it will melt to form a re-liquefied purified material. Any suitable apparatus can be used to melt the purified solidified material, e.g., top heaters. By melting the purified solidified material, concentration gradients formed in the purified solidified material will be eliminated.

If further purification is desired, i.e., if the batch of material is to be subjected to a further treatment cycle, the container and the re-liquefied purified material contained therein are again subjected to directional solidification, using an apparatus as described above as being suitable for performing directional solidification. In one aspect of the present invention, where such further directional solidification is desired, the melting of the purified solidified material can be carried out in the apparatus in which the raw material was previously melted, and/or the further directional solidification can be carried out in the apparatus in which the previous directional solidification was carried out (i.e., the batch can be recycled through the melting and/or the solidifying apparatuses).

If no further purification is desired, the re-liquefied purified material is either removed from the container as a liquid or again solidified in the container, e.g. to form an ingot. The re-liquefied purified material can be removed from the container as a liquid using any suitable apparatus. For example, one example of a preferred apparatus for removing the liquid remainder is a tipping device which, like the device described above for removing the liquid remainder, tips the container so as to pour the re-liquefied purified material into a receptacle for capturing and cooling and/or solidifying the purified material (e.g., forming ingots or dropping from a height so as to segregate and/or splash and solidify as particulate material), or into a device for use in further processing the purified material, e.g., forming it into wafers (for example, the re-liquefied purified material can be supplied directly into setters and processed as described in U.S. patent application Ser. No. 60/404,506, entitled “METHOD AND APPARATUS FOR MANUFACTURING NET SHAPE SEMICONDUCTOR WAFERS,” Ralf Jonczyk, Scott Kendall, James Rand, attorney docket no. 857_{—}033, filed Aug. 19, 2002, the entirety of which is hereby incorporated herein by reference, or processed as described in U.S. Pat. Nos. 6,207,891, 6,111,191, RE 36,156 and 5,496,416, the entireties of which are each hereby incorporated by reference).

This procedure has the advantage of allowing the container to remain close to the melting temperature of silicon (>1400° C.), thus extending the lifetime of the container, and simplifying the process for removing the purified material from the container. In addition, where solidification proceeds generally upward, the expansion of silicon upon freezing can be accommodated without the containers breaking.

As mentioned above, if the re-liquefied purified material is suitably pure, it can be employed in liquid form in further processing, or it can be solidified in the form of one or more ingots and/or particles. Any suitable solidification process can be employed, so long as such process does not result in unacceptable contamination of the purified material. For instance, an example of a suitable method for solidifying the purified material in the form of particles includes dropping droplets of the purified material from a height (e.g., eight feet) so that upon splashing, the purified material solidifies in the form of particles. An example of a suitable method for solidifying the purified material in the form of an ingot includes depositing the purified material in an ingot mold (e.g., formed of graphite with a coating of a release agent). For later use, the solidified material is sized, if necessary, and processed according to any suitable method, e.g., to make Czochralski-ingots, wafers (e.g., as described in U.S. patent application Ser. No. 60/404,506, entitled “METHOD AND APPARATUS FOR MANUFACTURING NET SHAPE SEMICONDUCTOR WAFERS,” Ralf Jonczyk, Scott Kendall, James Rand, attorney docket no. 857_{—}033, filed Aug. 19, 2002), or sheets (as described in U.S. Pat. Nos. 6,207,891, 6,111,191, RE 36,156 and 5,496,416). For example, if necessary, the solidified material can be crushed by any suitable comminution method. In any such method, particular attention must be paid to ensuring that the method does not lead to the addition of unacceptable amounts of impurities.

As described above, if desired, after being subjected to a purification treatment cycle as described above, a batch of material can be subjected to a second (or more) purification treatment cycle (or cycles). Such an additional treatment cycle can be carried out by again directionally solidifying part of the batch (i.e., after the material has been re-liquefied) to form solidified re-purified material, and then removing the remaining liquid. Optionally, the solidified re-purified material can then be melted to form a re-liquefied re-purified material. In such a multiple treatment cycle process, the batch is subjected to a thermal profile that effects a first directional solidification, the liquid remainder is removed, and the purified solidified material is preferably then re-liquefied before being subjected to a thermal profile that effects a second directional solidification.

The system for use in carrying out the methods of the present invention can include any suitable apparatuses for performing the desired parts included in the method. For example, any suitable apparatus can be employed for depositing raw material in a container, any suitable apparatus can be employed for subjecting raw material to conditions under which the raw material will liquify, any suitable apparatus can be employed for subjecting liquefied raw material to a thermal profile that effects directional solidification, any suitable apparatus can be employed for removing a liquid remainder, any suitable apparatus can be employed for melting purified solidified material, and/or any suitable apparatus can be employed for removing re-liquefied purified material. In addition, the system can include any suitable apparatus for moving the container from one apparatus to the next (e.g., for moving a container from an apparatus for depositing raw material in the container, to an apparatus for subjecting the raw material to conditions under which the raw material will liquify, etc.). Preferably, the various apparatuses are within a single structure, e.g., positioned in or constituting zones within a structure.

The respective apparatuses preferably do not cause any substantial contamination of the material being purified. For example, apparatus for heating the material and/or containers in which the material is positioned can suitably be formed of graphite. Similarly, apparatus for cooling the material and/or the containers can be formed, e.g., of graphite or aluminum.

The apparatus for moving the container from one apparatus to the next can move the container intermittently or continuously (or any combination of intermittent and continuous motion), as desired. For example, in one aspect of the invention, the container can be moved substantially continuously from an apparatus for depositing raw material in a container to an apparatus for melting the raw material, then to an apparatus for subjecting the liquefied raw material to a thermal profile that effects directional solidification, then to an apparatus for removing the liquid remainder, then to an apparatus for re-melting the purified solidified material, and then to an apparatus for removing the re-liquefied purified material from the container. Alternatively, the container can be moved intermittently from each such apparatus to the next, or the container can be moved intermittently through part of the treatment cycle, and continuously through another part (or parts) of the treatment cycle.

As noted above, according to, an aspect of the present invention, the containers can be recycled, such that after a batch contained in a container has been moved through one or more treatment cycles and removed from the container, the container can be moved back to the apparatus for depositing a new batch of raw material into the container, and the container is then moved through one or more treatment cycles to purify the new batch of raw material. Preferably, in such recycling, the containers remain at an elevated temperature. For example, the containers are at an elevated temperature as a result of re-liquefying purified material at the end of one treatment cycle, and at the beginning of the next treatment cycle, raw material is deposited in the containers while the containers are still at an elevated temperature. As a result, the containers are at elevated temperatures substantially continuously throughout the operation of the continuous process. By so doing, energy is conserved because less heat is lost from the containers to the surroundings. In instances where the raw material is solid as it is deposited into the containers, heat transferred from the containers to the raw material goes toward melting the raw material-as a result, the amount of energy supplied to the process is more close to the amount of energy required to melt and re-melt the raw material (energy is not needed to raise the temperature of recycled containers from a lower temperature, e.g., ambient temperature, up to the melting point of the material being purified).

The system preferably has a controlled atmosphere, at least where the raw material is melted, where the raw material is heated, where part of the melted raw material is directionally solidified, where the remaining liquid is removed and/or where the purified material is re-melted. Where such a controlled atmosphere is employed, the atmosphere is preferably sealed from the surrounding environment using any suitable seals.

Preferred gases deployed in the raw material melting zone include argon, nitrogen, hydrogen, water, ammonia, and combinations thereof, wet argon (argon and water), optionally in combination with hydrogen, being particularly preferred, e.g., where the material being purified is silicon, to assist in removing impurities such as boron. Preferably, process gases are removed to remove residual process gases generated in both the raw material melting apparatus and in the directional solidification apparatus. In a preferred embodiment, the gas deployed in the melting apparatus and in the directional solidification apparatus during a first treatment cycle is a combination of argon, water and hydrogen. In a further preferred embodiment, the gas deployed in the melting apparatus and the directional solidification apparatus during a second treatment cycle is a combination of nitrogen, water and ammonia. Other methods of treating raw materials are described in U.S. patent application Ser. No. 09/933,882, entitled METHOD AND APPARATUS FOR PURIFYING SILICON, filed Aug. 21, 2001, the entirety of which is hereby incorporated by reference.

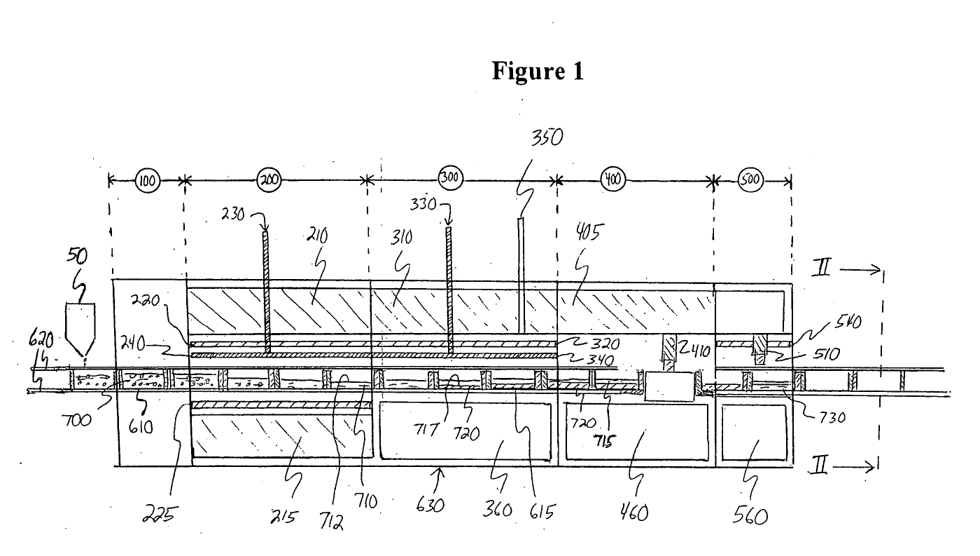

FIG. 1 is a schematic representation of an embodiment of a continuous uni-directional solidification furnace suitable for use in accordance with the present invention. This particular embodiment is specifically directed to purification of silicon. In this embodiment, there are five major zones in the furnace: an entrance zone 100, a silicon feedstock melting zone 200, a uni-directional solidification zone 300, an impurity pour zone 400, and a purified silicon exit zone 500.

The continuous uni-directional solidification process according to this embodiment is initiated by placing solid silicon feedstock 700 (e.g., using a hopper 50 to feed particulate silicon) into a containment boat having a depth of about 12 cm.

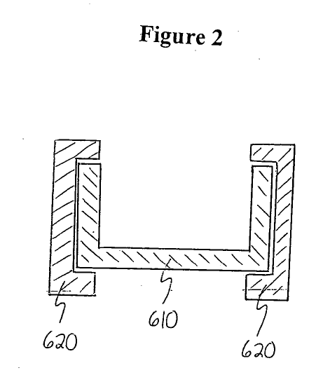

The boat containing the silicon feedstock 610 is positioned on a set of transport rails 620 and is pushed through the entire furnace, e.g, by being pushed by the next following boat, which in turn is pushed by the next following boat or by a pushing device. An embodiment of the transport rails 620 is shown in cross-section in FIG. 2. The boat may be moved continuously through the furnace, or may proceed by making sequential stops at designated points along the length of the furnace that have specified thermal conditions established.

The boat containing the silicon feedstock 610 enters the furnace at the entrance zone 100 where a transition from the air atmosphere to a gaseous atmosphere is accomplished.

In the silicon feedstock-melting zone 200, melting of the silicon is accomplished using planar heaters that are placed both above 220 and below 225 the work being transported through the zone. Primarily, the top heaters 220 are utilized during the heat-up of the solid silicon feedstock 700 so that melting of the silicon occurs from the top down. In this embodiment, these heaters are planar in extent, having a serpentine heater element configuration, and are fabricated from graphite.

In this zone ample insulation is used in both the top 210 and bottom 215 of the furnace (as well as the sides-not shown) to minimize heat losses and to help in the establishment of constant thermal gradients.

The desired ambient -conditions are established by introducing process gases 230 through a plenum 240 into a muffle chamber. The bottom and sides of the muffle chamber are created by the boat containing the silicon feedstock 610 and the boat transport rails 620, respectively. The gases deployed in this silicon feedstock-melting zone 200 and in the uni-directional solidification zone 300 during a first uni-directional solidification purification pass are a combination of argon, water and hydrogen, and the gases deployed in the silicon feedstock melting zone 200 and the uni-directional solidification zone 300 during a second uni-directional solidification purification pass (if carried out) are a combination of nitrogen, water and ammonia. Residual process gases generated in both the silicon feedstock 200 and uni-directional solidification 300 zones are removed via a pipe 350.

In the uni-directional solidification zone 300, the fully melted silicon feedstock 710 that emerges from the silicon feedstock melting zone 200 is uni-directionally solidified. Similar to the silicon feedstock-melting zone 200, top heaters 320 and thermal insulation 310 are utilized in the unidirectional solidification zone 300 to provide heat to the top of the work and to minimize heat loss, respectively. The desired ambient conditions are established by introducing process gases 330 through a plenum 340 into the muffle chamber.

When the fully melted silicon feedstock 710 enters the uni-directional solidification zone 300, it is completely melted, and may, depending on the process gases used and the incorporation of oxide additives (e.g. silicon oxide and/or silicon nitride), have a slag floating on the top surface 712. As previously indicated, it is the role of this slag to preferentially gather impurities from the liquid silicon.

The management of energy in the uni-directional solidification zone 300 is accomplished by employing top heaters 320 and controlling the rate of heat removal 360 from the bottom. The top thermal insulation 310 is used to enhance the efficiency of the top heaters 320.

When heat is initially removed preferentially from the fully melted silicon feedstock 710 through the bottom surface 615 of the boat, purified solid silicon 720 is formed leading to a planar liquid/solid interface 717. Control of the top heaters 320 in conjunction with the heat removal using a cooling device 360 allows for the continual control of the rate at which the planar solid/liquid solidification front 717 advances.

The rate of heat removal is controlled in this embodiment by moderating radiation transfer from the bottom surface 615 of the boat. In a preferred embodiment, a low (nominally room) temperature radiation surface is provided by water-cooling a section of the outer metallic surface of the furnace 630. In this configuration the high temperature bottom surface 615 of the boat is at a temperature of approximately 1700° K., and this radiates to the water-cooled section of the outer metallic surface 630 of the furnace at a temperature of 300° K. Radiation plates are deployed between the bottom surface 615 of the boat and the water-cooled section of the outer metallic surface 630 of the furnace to moderate the rate into the desired range.

In the impurity pour zone 400, the impurity-laden liquid silicon 715 is removed from the purified solidified silicon 720. Insulation 405 is provided in the impurity pour zone 400. In this zone, a tipper 410 pushes on a hinged section of the transport rails in order to tip the boat 610 containing the silicon so as to pour of the impurity-laden liquid silicon 715 from the purified, solidified silicon 720 into a receptacle 460 for capturing and cooling the impurity-laden liquid silicon 715.

The boat containing the purified solidified silicon 720 finally enters the purified silicon exit zone 500, in which the purified solidified silicon 720 is melted using top heaters 540. The next step depends on whether or not a second directional solidification purification step is desired. If a second purification pass is not desired, then a tipper 510 tips the boat 610 to pour the purified, re-liquefied silicon 730 into a receptacle 560 for capturing the purified re-liquefied silicon 730.

If a second purification sequence is desired, the boat 610 containing the singly-purified silicon 730 that has been melted in zone 500 can now repeat the process by entering a zone similar to the uni-directional solidification zone 300 (or entering the uni-directional solidification zone 300) and from there proceeding to a zone similar to the impurity pour zone 400 (or proceeding to the impurity pour zone 400), and then to a zone similar to the purified silicon exit zone 500 (or proceeding to the purified silicon exit zone 500) where the twice-purified silicon can be extracted. This process sequence can be repeated as many times as is desired to achieve the desired purification of the silicon.

1. A method of purifying a material, comprising:
melting solid material to form liquefied material;
directionally solidifying a portion of said liquefied material to convert said liquefied material to a combination of purified solidified material and liquid remainder;
removing said liquid remainder from said purified solidified material; and
melting said purified solidified material to form re-liquefied purified material.

2. A method as recited in claim 1, wherein said solid material comprises recycle scrap silicon and/or metallurgical grade silicon.

3. A method as recited in claim 1, further comprising at least one additional treatment cycle on said purified material, each said additional treatment cycle comprising directional solidification, liquid remainder removal and melting.

4. A method as recited in claim 1, wherein during said directional solidification, a solidification front travels from a bottom of said liquefied material substantially upward toward a top of said liquefied material at a rate of from about 0.1 cm/minute to about 0.2 cm/minute.

5. A method as recited in claim 1, wherein said solid material comprises at least about 95% by weight silicon.

6. A method as recited in claim 1, wherein said purified solidified material has a mass which is from about 85% to about 95% of a mass of said liquefied material.

7. A method as recited in claim 1, further comprising adding to said solid material at least one oxide additive and/or at least one nitride additive.

8. A method as recited in claim 7, wherein said oxide additive is silicon oxide and said nitride additive is silicon nitride.

9. A method as recited in claim 1, wherein said purified solidified material has a depth of not more than about 10 cm.

10. A method of purifying a material, comprising:
depositing solid material in a container;
melting said solid material to form liquefied material;
directionally solidifying a portion of said liquefied material to convert said liquefied material to a combination of purified solidified material and liquid remainder;
removing said liquid remainder from said container;
melting said purified solidified material to form re-liquefied purified material; and
removing said re-liquefied purified material from said container.

11. A method as recited in claim 10, wherein said solid material comprises recycle scrap silicon and/or metallurgical grade silicon.

12. A method as recited in claim 10, further comprising removing said re-liquefied purified material from said container.

13. A method as recited in claim 10, further comprising recycling said container and purifying at least one additional batch of solid material by depositing said additional batch of solid material in said container, melting said additional batch of solid material to form an additional batch of liquefied material, directionally solidifying a portion of said additional batch of liquefied material to form an additional batch of purified solidified material and an additional batch of liquid remainder, removing said additional batch of liquid remainder from said container, melting said additional batch of purified solidified material to form an additional batch of re-liquefied purified material; and removing said additional batch of re-liquefied material from said container.

14. A method as recited in claim 10, further comprising at least one additional treatment cycle on said purified material, each said additional treatment cycle comprising directional solidification, liquid remainder removal and re-melting.

15. A method as recited in claim 10, wherein during said directional solidification, a solidification front travels from a bottom of said liquefied material substantially upward toward a top of said liquefied material at a rate of from about 0.1 cm/minute to about 0.2 cm/minute.

16. A method as recited in claim 10, wherein said solid material comprises at least about 95% by weight silicon.

17. A method as recited in claim 10, wherein said purified solidified material has a mass which is from about 85% to about 95% of a mass of said liquefied material.

18. A method as recited in claim 10, further comprising adding to said solid material at least one oxide additive and/or at least one nitride additive.

19. A method as recited in claim 18, wherein said oxide additive is silicon oxide and said nitride additive is silicon nitride.

20. A method as recited in claim 10, wherein said purified solidified material has a depth of not more than about 10 cm.

21. A method of purifying a material, comprising:
melting solid material to form liquefied material, said solid material comprising at least 95% silicon or at least 95% germanium;
directionally solidifying a portion of said liquefied material to convert said liquefied material to a combination of purified solidified material and liquid remainder; and
removing said liquid remainder from said purified solidified material.

22. A method of purifying a material, comprising:
depositing solid material in each of a plurality of containers; and
moving each of said containers in sequence through positions where:
said solid material in each said container is melted to form liquefied material;
a portion of said liquefied material in each said container is directionally solidified to convert said liquefied material to a combination of purified solidified material and liquid remainder;
said liquid remainder in each said container is removed from said container;
said purified solidified material in each said container is melted to form re-liquefied purified material; and
said re-liquefied purified material in each said container is removed from said container.

23. A method as recited in claim 22, further comprising recycling each said container and purifying at least one additional batch of solid material in each said container by depositing said additional batch of solid material in each said container, melting said additional batch of solid material to form an additional batch of liquefied material, directionally solidifying a portion of said additional batch of liquefied material to form an additional batch of purified solidified material and an additional batch of liquid remainder, removing said additional batch of liquid remainder from each said container, melting said additional batch of purified solidified material to form an additional batch of re-liquefied purified material; and removing said additional batch of re-liquefied material from each said container.

24. A method as recited in claim 22, further comprising performing at least one additional treatment cycle on said purified material, each said additional treatment cycle comprising directional solidification, liquid remainder removal and re-melting.

25. A system for purifying a material, comprising:
at least one container;
a first melter which can create conditions under which a material being treated will melt to form a liquefied material;
a solidifier which can create conditions under which a part of said liquefied material will directionally solidify to convert said liquefied material to a combination of purified solidified material and liquid remainder;
a liquid remover which can remove said liquid remainder from said container; and
a second melter which can create conditions under which said purified solidified material melts to form a re-liquefied purified material.

26. A system as recited in claim 25, further comprising:
a material supplier which can supply material to said container; and
a second liquid remover which can remove said re-liquefied purified material from said container.

27. A system as recited in claim 25, wherein said liquid remover comprises a tipper which can tip said container to pour said liquid remainder out of said container.

28. A system as recited in claim 25, further comprising at least one radiation plate positioned such that during at least part of the time when said container is in said solidifier, said radiation plate will be between said solidifier and said container.

29. A system for purifying silicon and/or germanium, comprising:
at least one container;
a first heating zone which can create conditions under which silicon and/or germanium will melt to form a liquefied material;
a thermal treatment zone which can create conditions under which a part of said liquefied material will directionally solidify to convert said liquefied material to a combination of purified solidified material and liquid remainder;
a liquid remover which can remove said liquid remainder from said container; and
a second heating zone which can create conditions under which said purified solidified material melts to form a re-liquefied purified material.

30. A system as recited in claim 29, wherein said liquid remover comprises a tipper which can tip said container to pour said liquid remainder out of said container.

31. A system as recited in claim 29, wherein said thermal treatment zone comprises at least one cooling device and at least one radiation plate positioned where it will be between said cooling device and said container at least part of the time when said container is in said thermal treatment zone.
